(19) United States
(12) Patent Application Publication
(10) Pub. No.: US 2026/0219796 A1
(43) Pub. Date: Jul. 30, 2026

(54) STORAGE DEVICE, OPERATION METHOD OF STORAGE DEVICE, AND NONVOLATILE MEMORY DEVICE OF STORAGE DEVICE

(71) Applicant: Samsung Electronics Co., Ltd., Suwon-si (KR)

(72) Inventors: Hongjin Kim, Suwon-si (KR); Ki-Hong Jeong, Suwon-si (KR)

(21) Appl. No.: 19/346,700

(22) Filed: Oct. 1, 2025

(30) Foreign Application Priority Data
Jan. 24, 2025 (KR) 10-2025-0011518

(51) Int. Cl. G06F 3/06

(52) U.S. Cl. CPC G06F 3/0634; G06F 3/0611; G06F 3/0659; G06F 3/0688

(57) ABSTRACT

Disclosed is a storage device which includes a plurality of nonvolatile memory devices, and a storage controller that selects one of the plurality of nonvolatile memory devices by controlling a plurality of chip enable signals to be transferred to the plurality of nonvolatile memory devices. The storage controller uses one of the plurality of chip enable signals as a reduced chip enable signal and remaining chip enable signals as chip enable address signals. The storage controller selects one of the plurality of nonvolatile memory devices by activating the reduced chip enable signal and controlling the chip enable address signals. The storage controller generates each of the chip enable address signals by using one of at least three voltage levels.

### CROSS-REFERENCE TO RELATED APPLICATIONS

This application claims priority under 35 U.S.C. § 119 to Korean Patent Application No. 10-2025-0011518 filed on January 24, 2025, in the Korean Intellectual Property Office, the disclosure of which is incorporated by reference herein in its entirety.

### BACKGROUND

A storage device may store data depending on a request of a host device. The storage device may include a nonvolatile memory device such as a flash memory device, a phase-change memory device, a ferroelectric memory device, a magnetic memory device, and a resistive memory device and may store data in the nonvolatile memory device. Accordingly, data written in the storage device by the host device may be retained in the storage device even though a power is removed from the storage device.

The storage device may include one storage controller and a plurality of nonvolatile memory devices. The storage device may use control signals for independently identifying the plurality of nonvolatile memory devices. As the number of nonvolatile memory devices included in the storage device increases, the number of control signals for identifying the nonvolatile memory devices may increase. Accordingly, the area and the complexity of the nonvolatile memory devices may increase.

### SUMMARY

Implementations of the present disclosure provide a storage device with the reduced area and complexity and improved expandability in association with control signals for identifying nonvolatile memory devices, an operation method of the storage device, and a nonvolatile memory device of the storage device.

According to some implementations, a storage device includes a plurality of nonvolatile memory devices, and a storage controller that selects one of the plurality of nonvolatile memory devices by controlling a plurality of chip enable signals to be transferred to the plurality of nonvolatile memory devices. The storage controller uses one of the plurality of chip enable signals as a reduced chip enable signal and remaining chip enable signals as chip enable address signals. The storage controller selects one of the plurality of nonvolatile memory devices by activating the reduced chip enable signal and controlling the chip enable address signals. The storage controller generates each of the chip enable address signals by using one of at least three voltage levels.

According to some implementations, an operation method of a storage device which includes a plurality of nonvolatile memory devices and a storage controller includes activating, at the storage controller, a reduced chip enable signal to be transferred to the plurality of nonvolatile memory devices, and generating, at the storage controller, each of chip enable address signals to be transferred to the plurality of nonvolatile memory devices by using one of at least three voltage levels.

According to some implementations, a memory device includes a memory cell array that includes a plurality of memory cells, a row decoder that is connected to rows of the plurality of memory cells, a page buffer that is connected to columns of the plurality of memory cells, and control logic that receives a reduced chip enable signal and chip enable address signals from an external device and determines whether to activate the row decoder and the page buffer in response to the chip enable address signals. The control logic determines whether each of the chip enable address signals corresponds to any level among at least three voltage levels, in response to activation of the reduced chip enable signal.

### BRIEF DESCRIPTION OF THE FIGURES

The above and other objects and features of the present disclosure will become apparent by describing in detail implementations thereof with reference to the accompanying drawings.

FIG. 1 illustrates a storage device according to some implementations of the present disclosure.

FIG. 2 illustrates nonvolatile memory chips of a storage device according to some implementations of the present disclosure.

FIG. 3 illustrates an example of first to (M-1)-th chip enable address signals.

FIG. 4 illustrates an operation method of a storage device according to some implementations of the present disclosure.

FIG. 5 illustrates an example of first to (M-1)-th chip enable address signals generated by using one of at least three voltages.

FIG. 6 illustrates an example of first to (M-1)-th chip enable address signals generated by using one of at least four voltages.

FIG. 7 illustrates an example of some circuits of a storage controller according to some implementations of the present disclosure.

FIG. 8 illustrates an example of some circuits of first to N-th nonvolatile memory chips of a nonvolatile memory device according to some implementations of the present disclosure.

FIG. 9 illustrates an operation method of a storage device according to some implementations of the present disclosure.

FIG. 10 illustrates an application example of an operation method of a storage device according to some implementations of the present disclosure.

FIG. 11 illustrates a storage device according to other implementations of the present disclosure.

FIG. 12 illustrates a storage device according to other implementations of the present disclosure.

FIG. 13 illustrates a block diagram of a nonvolatile memory chip according to some implementations of the present disclosure.

FIG. 14 illustrates a diagram of a system to which a storage device is applied, according to some implementations of the present disclosure.

### DETAILED DESCRIPTION

Below, implementations of the present disclosure will be described in detail and clearly to such an extent that an ordinary one in the art easily carries out the present disclosure.

Implementations of the present disclosure described herein relate to an electronic device, and more particularly, relate to a storage device with the reduced area and complexity and improved expandability, an operation method of the storage device, and a nonvolatile memory device of the storage device.

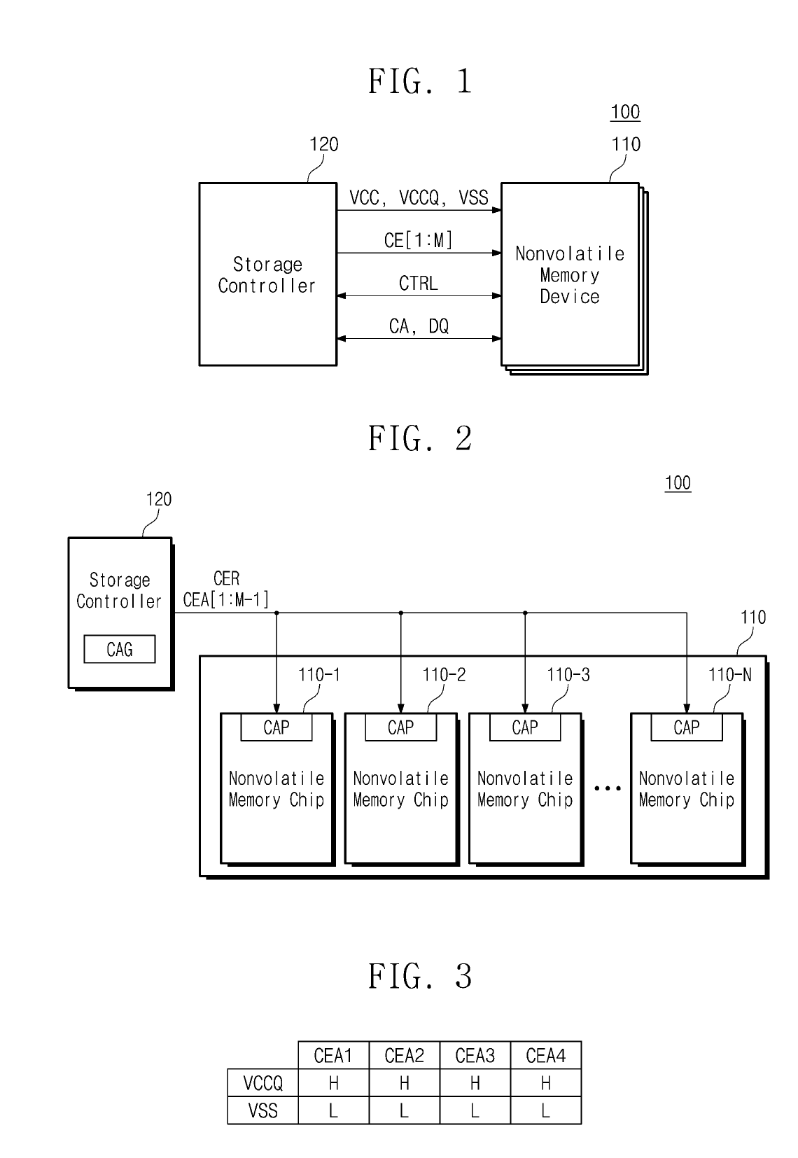

FIG. 1 illustrates a storage device 100 according to some implementations of the present disclosure. Referring to FIG. 1, the storage device 100 may include a nonvolatile memory device 110 and a storage controller 120.

The nonvolatile memory device 110 may include a plurality of nonvolatile memory devices, for example, a plurality of nonvolatile memory chips. The plurality of nonvolatile memory chips of the nonvolatile memory device 110 may be controlled by the storage controller 120.

The storage controller 120 may supply voltages (or a power) to the plurality of nonvolatile memory chips of the nonvolatile memory device 110 in common. For example, the storage controller 120 may supply a power supply voltage VCC, a data communication power supply voltage VCCQ, and a ground voltage VSS to the plurality of nonvolatile memory chips of the nonvolatile memory device 110 in common.

The power supply voltage VCC may be a power supply voltage of a logic high level which each nonvolatile memory chip of the nonvolatile memory device 110 uses for an internal operation. The ground voltage VSS may be a ground voltage of a logic low level which each nonvolatile memory chip of the nonvolatile memory device 110 uses for an internal operation and data communication (e.g., data communication with the storage controller 120). The data communication power supply voltage VCCQ may be a power supply voltage of a logic high level which each nonvolatile memory chip of the nonvolatile memory device 110 uses for the data communication with the storage controller 120. For example, the data communication power supply voltage VCCQ may be lower than the power supply voltage VCC.

The storage controller 120 may transmit first to M-th chip enable signals CE[1:M] to the plurality of nonvolatile memory chips of the nonvolatile memory device 110. In some implementations, the first to M-th chip enable signals CE[1:M] may be transferred through chip enable signal lines connected in common between the storage controller 120 and the plurality of nonvolatile memory chips of the nonvolatile memory device 110.

The storage controller 120 may independently identify and select the plurality of nonvolatile memory chips of the nonvolatile memory device 110 by using the first to M-th chip enable signals CE[1:M]. The logic high level of the first to M-th chip enable signals CE[1:M] may correspond to the data communication power supply voltage VCCQ, and the logic low level thereof may correspond to the ground voltage VSS.

The storage controller 120 may transmit control signals CTRL to the plurality of nonvolatile memory chips of the nonvolatile memory device 110. In some implementations, the control signals CTRL may be transferred through control signal lines connected in common between the storage controller 120 and the plurality of nonvolatile memory chips of the nonvolatile memory device 110.

The storage controller 120 may control operations of the plurality of nonvolatile memory chips of the nonvolatile memory device 110, for example, an operation of a nonvolatile memory chip selected by the first to M-th chip enable signals CE[1:M] by using the control signals CTRL. The logic high level of the control signals CTRL may correspond to the data communication power supply voltage VCCQ, and the logic low level thereof may correspond to the ground voltage VSS.

In some implementations, the control signals CTRL may include unidirectional signals which are transmitted from the storage controller 120 to the plurality of nonvolatile memory chips of the nonvolatile memory device 110, unidirectional signals which are transmitted from the plurality of nonvolatile memory chips of the nonvolatile memory device 110 to the storage controller 120, and bidirectional signals which are communicated between the storage controller 120 and the plurality of nonvolatile memory chips of the nonvolatile memory device 110.

The storage controller 120 may communicate a command and address CA and data DQ with the plurality of nonvolatile memory chips of the nonvolatile memory device 110. In some implementations, the command and address CA may be transferred through command and address signal lines connected in common between the storage controller 120 and the plurality of nonvolatile memory chips of the nonvolatile memory device 110. The data DQ may be transferred through data signal lines connected in common between the storage controller 120 and the plurality of nonvolatile memory chips of the nonvolatile memory device 110.

The logic high level of the command and address CA may correspond to the data communication power supply voltage VCCQ, and the logic low level thereof may correspond to the ground voltage VSS. The logic high level of the data DQ may correspond to the data communication power supply voltage VCCQ, and the logic low level thereof may correspond to the ground voltage VSS.

In some implementations, the command and address signal lines and the data signal lines may be signal lines separated from each other. That is, the command and address CA and the data DQ may be transferred through different signal lines. As another example, the command and address signal lines and the data signal lines may be the same signal lines. That is, the command and address CA and the data DQ may be transferred through the same signal lines.

The storage controller 120 may transmit the command and address CA to the command and address signal lines. A nonvolatile memory chip selected by the first to M-th chip enable signals CE[1:M] from among the plurality of nonvolatile memory chips of the nonvolatile memory device 110 may receive and parse the command and address CA through the command and address signal lines. The selected nonvolatile memory chip may operate in response to a result of parsing the command and address CA. For example, the selected nonvolatile memory chip may perform the write operation, the read operation, or the erase operation.

The storage controller 120 may communicate the data DQ with the selected nonvolatile memory chip among the plurality of nonvolatile memory chips of the nonvolatile memory device 110. For example, the storage controller 120 may transmit the data DQ to the data signal lines. The selected nonvolatile memory chip may receive the data DQ through the data signal lines. As another example, the selected nonvolatile memory chip may transmit the data DQ to the data signal lines. The storage controller 120 may receive the data DQ through the data signal lines.

In some implementations, each of signals communicated between the storage controller 120 and the plurality of nonvolatile memory chips of the nonvolatile memory device 110 requires a pad in the storage controller 120 and each nonvolatile memory chip of the nonvolatile memory device 110. The pad may be provided to be larger than typical semiconductor elements for connection with an external signal line. That is, the pad may act as a factor causing the increase in the area and complexity in the storage controller 120 and each nonvolatile memory chip of the nonvolatile memory device 110.

Voltages, the control signals CTRL, the command and address CA, and the data DQ are connected to common signal lines between the storage controller 120 and the plurality of nonvolatile memory chips of the nonvolatile memory device 110. Accordingly, even though the number of nonvolatile memory chips of the nonvolatile memory device 110 increases, the number of pads required in association with the voltages, the control signals CTRL, the command and address CA, and the data DQ may be maintained in the storage controller 120 and each nonvolatile memory chip of the nonvolatile memory device 110 without increase.

In some implementations, the first to M-th chip enable signals CE[1:M] may respectively correspond to the plurality of nonvolatile memory chips of the nonvolatile memory device 110. The storage controller 120 may generate one chip enable signal among the first to M-th chip enable signals CE[1:M] at the logic high (or low) level and may generate the remaining chip enable signals at the logic low (or high) level. A nonvolatile memory chip corresponding to the chip enable signal having the logic high (or low) level from among the plurality of nonvolatile memory chips of the nonvolatile memory device 110 may be selected by the storage controller 120.

That is, the number of nonvolatile memory chips of the nonvolatile memory device 110 may correspond to (or may be identical to) the number of first to M-th chip enable signals CE[1:M]. As the number of nonvolatile memory chips of the nonvolatile memory device 110 increases, the number of first to M-th chip enable signals CE[1:M] may increase, and the number of required pads may increase. The increase in the number of required pads may cause the increase in the area and complexity.

Below, the present disclosure provides implementations capable of preventing the increase in the number of pads required in association with the first to M-th chip enable signals CE[1:M] and reducing the area and complexity of the storage device 100.

FIG. 2 illustrates nonvolatile memory chips of the storage device 100 according to some implementations of the present disclosure. Referring to FIGS. 1 and 2, the nonvolatile memory device 110 may include first to N-th nonvolatile memory chips 110_1 to 110_N.

The storage controller 120 may transmit a reduced chip enable signal CER and first to (M-1)-th chip enable address signals CEA[1:M-1], as the first to M-th chip enable signals CE[1:M], to the first to N-th nonvolatile memory chips 110_1 to 110_N through common chip enable signal lines.

The reduced chip enable signal CER may indicate that the first to N-th nonvolatile memory chips 110_1 to 110_N are targeted for access and may indicate that the first to M-th chip enable signals CE[1:M] are controlled based on an address. For example, the reduced chip enable signal CER may indicate that some of the first to M-th chip enable signals CE[1:M] are used as chip enable address signals, for example, as the first to (M-1)-th chip enable address signals CEA[1:M-1].

The storage controller 120 may include a chip address generator CAG. The chip address generator CAG may generate the first to (M-1)-th chip enable address signals CEA[1:M-1] such that the first to N-th nonvolatile memory chips 110_1 to 110_N are identified and selected in an address manner.

In some implementations, in the example described with reference to FIG. 1, each of the first to M-th chip enable signals CE[1:M] may correspond to one nonvolatile memory chip. When the first to M-th chip enable signals CE[1:M] are used as the reduced chip enable signal CER and the first to (M-1)-th chip enable address signals CEA[1:M-1], each of patterns of the first to (M-1)-th chip enable address signals CEA[1:M-1] may correspond to one nonvolatile memory chip.

Each of the first to N-th nonvolatile memory chips 110_1 to 110_N may include a chip address parser CAP. The chip address parser CAP may identify a nonvolatile memory chip which the first to (M-1)-th chip enable address signals CEA[1:M-1] indicate when the reduced chip enable signal CER is activated. The chip address parser CAP of the nonvolatile memory chip which the first to (M-1)-th chip enable address signals CEA[1:M-1] indicate may activate the corresponding nonvolatile memory chip. For example, the activated nonvolatile memory chip may identify and communicate the control signals CTRL, the command and address CA, and the data DQ as a valid signal.

In some implementations, the first to (M-1)-th chip enable address signals CEA[1:M-1] may be distinguished from the address of the command and address CA. The first to (M-1)-th chip enable address signals CEA[1:M-1] may indicate one of the first to N-th nonvolatile memory chips 110_1 to 110_N. The address of the command and address CA may indicate one of storage spaces of the nonvolatile memory chip which the first to (M-1)-th chip enable address signals CEA[1:M-1] indicate.

FIG. 3 illustrates an example of the first to (M-1)-th chip enable address signals CEA[1:M-1]. In some implementations, an example in which “M” is 5 is illustrated in FIG. 3. Referring to FIGS. 2 and 3, the first to (M-1)-th chip enable address signals CEA[1:M-1] may include first to fourth chip enable address signals CEA1, CEA2, CEA3, and CEA4. The logic high level (H) of the first to fourth chip enable address signals CEA1, CEA2, CEA3, and CEA4 may be the data communication power supply voltage VCCQ, and the logic low level (L) thereof may be the ground voltage VSS.

The number of patterns of the first to fourth chip enable address signals CEA1, CEA2, CEA3, and CEA4 may be 2^4, that is, 16. That is, the storage controller 120 may identify and select 16 nonvolatile memory chips by using the first to fourth chip enable address signals CEA1, CEA2, CEA3, and CEA4.

In some implementations in which each chip enable signal identifies one nonvolatile memory chip, four chip enable signals may identify four nonvolatile memory chips. In some implementations in which each of the patterns of chip enable address signals identifies one nonvolatile memory chip, four chip enable signals may identify 16 nonvolatile memory chips. That is, assuming that the number of pads is identically maintained, when chip enable address signals are used, the number of nonvolatile memory chips which the storage controller 120 is capable of identifying may increase.

Likewise, when chip enable address signals are used, two chip enable address signals may be required to identify four nonvolatile memory chips. That is, when chip enable address signals are used to identify the same number of nonvolatile memory chips, the number of pads of chip enable address signals which each of the storage controller 120 and the nonvolatile memory chips requires may decrease.

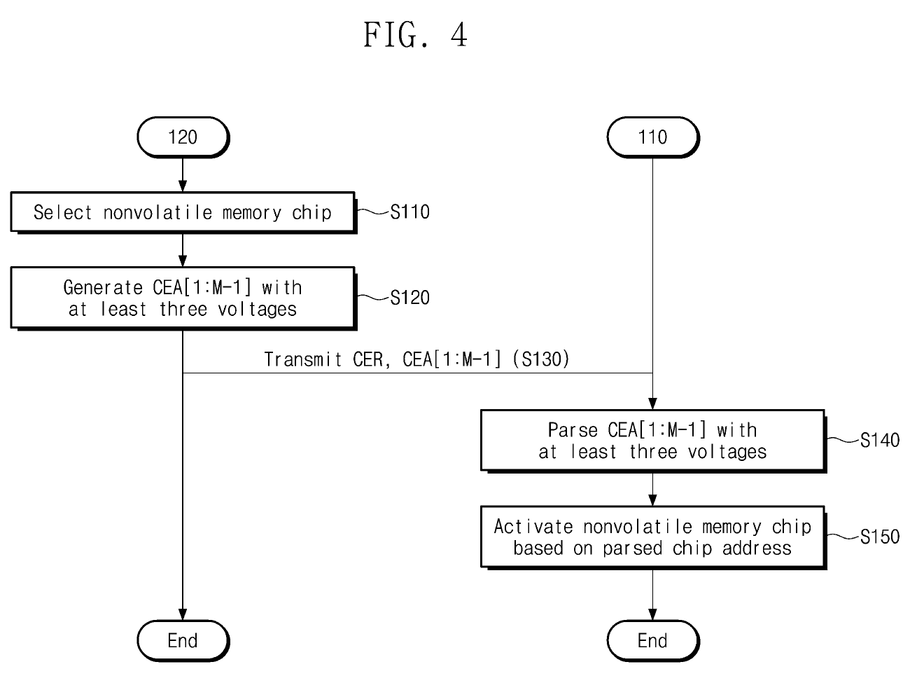

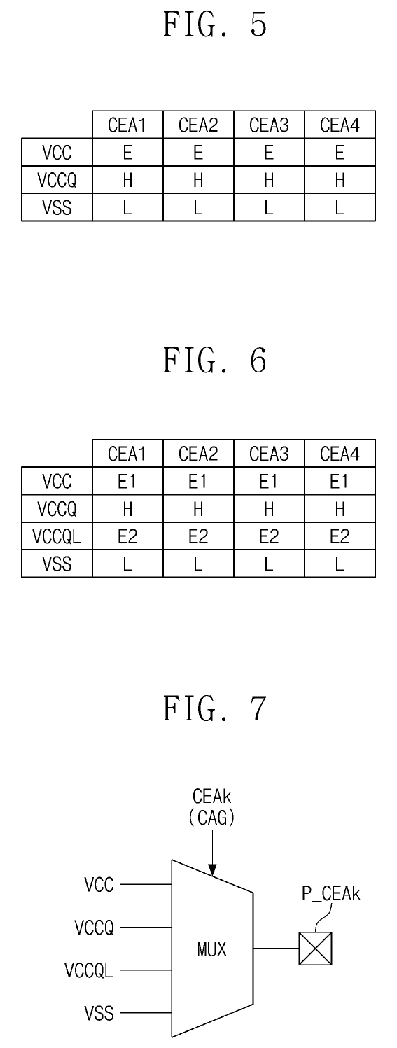

FIG. 4 illustrates an operation method of the storage device 100 according to some implementations of the present disclosure. Referring to FIGS. 2 and 4, in operation S110, the storage controller 120 may select a nonvolatile memory chip. For example, the storage controller 120 may select one nonvolatile memory chip targeted for an access (e.g., write, read, or erase) from among the first to N-th nonvolatile memory chips 110_1 to 110_N. For example, the storage controller 120 may select one nonvolatile memory chip depending on a request of an external host device or depending on a background operation performed based on internal policy.

In operation S120, the storage controller 120 may generate the first to (M-1)-th chip enable address signals CEA[1:M-1] by using at least three voltages. For example, the chip address generator CAG of the storage controller 120 may generate each of the first to (M-1)-th chip enable address signals CEA[1:M-1] by using a symbol having one of at least three levels. Patterns (or at least some of the patterns) of the symbols of the first to (M-1)-th chip enable address signals CEA[1:M-1] may respectively correspond to the first to N-th nonvolatile memory chips 110_1 to 110_N. The chip address generator CAG may generate each of the first to (M-1)-th chip enable address signals CEA[1:M-1] by using one of at least three voltages, such that a nonvolatile memory chip to be accessed is selected.

In operation S130, the storage controller 120 may transmit the reduced chip enable signal CER and the first to (M-1)-th chip enable address signals CEA[1:M-1] to the first to N-th nonvolatile memory chips 110_1 to 110_N of the nonvolatile memory device 110. For example, the storage controller 120 may activate the reduced chip enable signal CER to an active level (e.g., logic low or logic high) and may adjust voltages (or voltage levels) of the first to (M-1)-th chip enable address signals CEA[1:M-1] based on symbols generated by the chip address generator CAG.

In operation S140, the nonvolatile memory device 110 may parse the first to (M-1)-th chip enable address signals CEA[1:M-1] having at least three voltages. For example, while the reduced chip enable signal CER has the active level, each of the first to N-th nonvolatile memory chips 110_1 to 110_N may parse levels of the symbols of the first to (M-1)-th chip enable address signals CEA[1:M-1].

In operation S150, the nonvolatile memory device 110 may activate a nonvolatile memory chip based on the parsed chip address. For example, the patterns (or at least some of the patterns) of the symbols of the first to (M-1)-th chip enable address signals CEA[1:M-1] may respectively correspond to the first to N-th nonvolatile memory chips 110_1 to 110_N. Accordingly, the first to (M-1)-th chip enable address signals CEA[1:M-1] may be considered as indicating a chip address.

A nonvolatile memory chip (e.g., a selected nonvolatile memory chip) corresponding to the chip address from among the first to N-th nonvolatile memory chips 110_1 to 110_N may be activated. The activated nonvolatile memory chip may identify and communicate the control signals CTRL, the command and address CA, and the data DQ as valid signals. Deactivated nonvolatile memory chips may identify the control signals CTRL, the command and address CA, and the data DQ as invalid signals and may ignore the control signals CTRL, the command and address CA, and the data DQ.

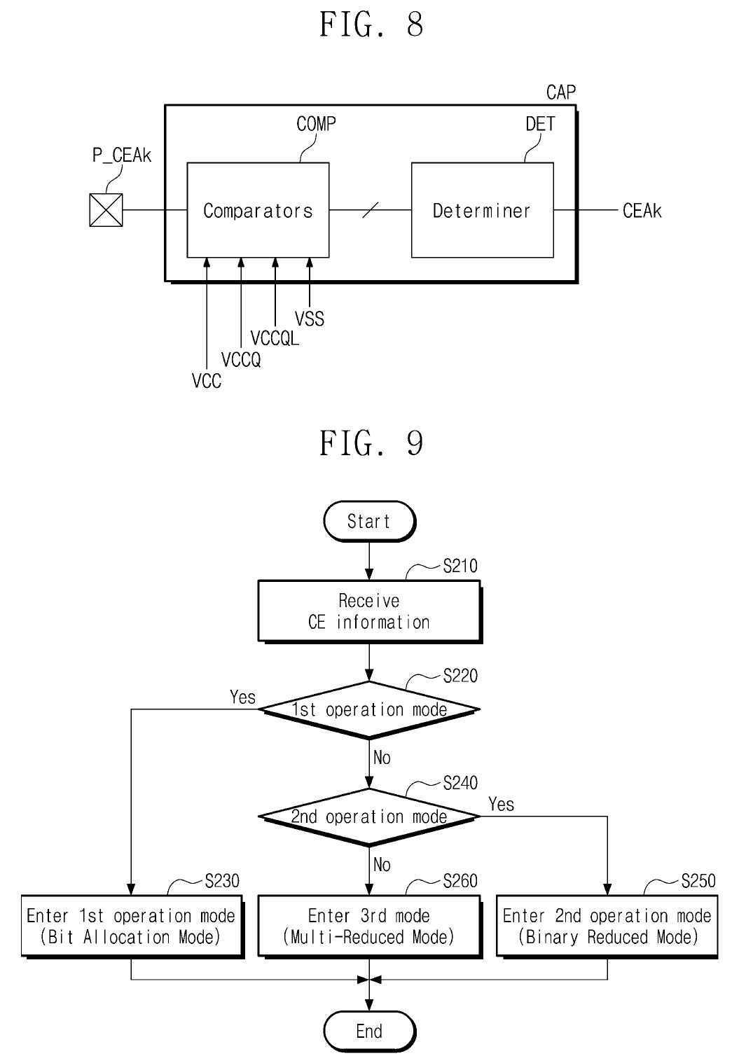

FIG. 5 illustrates an example of the first to (M-1)-th chip enable address signals CEA[1:M-1] generated by using one of at least three voltages. In some implementations, an example in which “M” is 5 is illustrated in FIG. 5. Referring to FIGS. 2 and 5, the first to (M-1)-th chip enable address signals CEA[1:M-1] may include the first to fourth chip enable address signals CEA1, CEA2, CEA3, and CEA4. The logic high level (H) of the first to fourth chip enable address signals CEA1, CEA2, CEA3, and CEA4 may be the data communication power supply voltage VCCQ, the logic low level (L) thereof may be the ground voltage VSS, and a logic extra level (E) thereof may be the power supply voltage VCC.

The number of patterns of the first to fourth chip enable address signals CEA1, CEA2, CEA3, and CEA4 may be 3^4, that is, 81. That is, the storage controller 120 may identify and select 81 nonvolatile memory chips by using the first to fourth chip enable address signals CEA1, CEA2, CEA3, and CEA4.

In some implementations in which each chip enable signal identifies one nonvolatile memory chip, four chip enable signals may identify four nonvolatile memory chips. In some implementations in which each of patterns of chip enable address signals generated by using two voltage levels identifies one nonvolatile memory chip, four chip enable signals may identify 16 nonvolatile memory chips. In some implementations in which each of patterns of chip enable address signals generated by using three voltage levels identifies one nonvolatile memory chip, four chip enable signals may identify 81 nonvolatile memory chips. That is, assuming that the number of pads is identically maintained, when chip enable address signals having three voltage levels are used, the number of nonvolatile memory chips which the storage controller 120 is capable of identifying may increase.

Likewise, when each chip enable signal identifies one nonvolatile memory chip, eight chip enable address signals may be required to identify eight nonvolatile memory chips. When chip enable address signals each having two voltage levels are used, three chip enable address signals may be required to identify eight nonvolatile memory chips. When chip enable address signals each having three voltage levels are used, two chip enable address signals may be required to identify eight nonvolatile memory chips. That is, when chip enable signals each having three voltage levels are used to identify the same number of nonvolatile memory chips, the number of pads of chip enable address signals required in each of the storage controller 120 and the nonvolatile memory chips may decrease.

The three voltage levels of the first to (M-1)-th chip enable address signals CEA[1:M-1], that is, the power supply voltage VCC, the data communication power supply voltage VCCQ, and the ground voltage VSS may be voltages which are supplied from the storage controller 120 to the first to N-th nonvolatile memory chips 110_1 to 110_N of the nonvolatile memory device 110. Without needing to generate a separate voltage level in the first to N-th nonvolatile memory chips 110_1 to 110_N and without needing to receive a separate voltage from the storage controller 120, the first to N-th nonvolatile memory chips 110_1 to 110_N may identify the levels of the first to (M-1)-th chip enable address signals CEA[1:M-1] by using the power supply voltage VCC, the data communication power supply voltage VCCQ, and the ground voltage VSS which are supplied from the storage controller 120.

FIG. 6 illustrates an example of the first to (M-1)-th chip enable address signals CEA[1:M-1] generated by using one of at least four voltages. In some implementations, an example in which “M” is 5 is illustrated in FIG. 6. Referring to FIGS. 2 and 6, the first to (M-1)-th chip enable address signals CEA[1:M-1] may include the first to fourth chip enable address signals CEA1, CEA2, CEA3, and CEA4.

The logic high level (H) of the first to fourth chip enable address signals CEA1, CEA2, CEA3, and CEA4 may be the data communication power supply voltage VCCQ, the logic low level (L) thereof may be the ground voltage VSS, a first logic extra level (E1) thereof may be the power supply voltage VCC, and a second logic extra level (E2) thereof may be a channel communication power supply voltage VCCQL.

In some implementations, the data communication power supply voltage VCCQ may be a power supply voltage which is used by circuits (e.g., a buffer circuit, a transmitter, and a receiver) for communicating with the storage controller 120 in the first to N-th nonvolatile memory chips 110_1 to 110_N. The channel communication power supply voltage VCCQL may be a power supply voltage of signals which are used for the first to N-th nonvolatile memory chips 110_1 to 110_N to communicate with the storage controller 120. For example, the logic high level of the control signals CTRL, the command and address CA, and the data DQ may be the channel communication power supply voltage VCCQL. For example, the level of the channel communication power supply voltage VCCQL may be lower than the level of the data communication power supply voltage VCCQ.

In some implementations, as described with reference to the power supply voltage VCC, the data communication power supply voltage VCCQ, and the ground voltage VSS in FIG. 1, the channel communication power supply voltage VCCQL may be transferred from the storage controller 120 to the first to N-th nonvolatile memory chips 110_1 to 110_N of the nonvolatile memory device 110. In some implementations, an example of the channel communication power supply voltage VCCQL is described, but an arbitrary voltage which the storage controller 120 provides to the first to N-th nonvolatile memory chips 110_1 to 110_N for the operations of the first to N-th nonvolatile memory chips 110_1 to 110_N of the nonvolatile memory device 110 may be applied to and used in implementations of the present disclosure.

The number of patterns of the first to fourth chip enable address signals CEA1, CEA2, CEA3, and CEA4 may be 4^4, that is, 256. That is, the storage controller 120 may identify and select 256 nonvolatile memory chips by using the first to fourth chip enable address signals CEA1, CEA2, CEA3, and CEA4.

In some implementations in which each chip enable signal identifies one nonvolatile memory chip, four chip enable signals may identify four nonvolatile memory chips. In some implementations in which each of patterns of chip enable address signals generated by using two voltage levels identifies one nonvolatile memory chip, four chip enable signals may identify 16 nonvolatile memory chips.

In some implementations in which each of patterns of chip enable address signals generated by using three voltage levels identifies one nonvolatile memory chip, four chip enable signals may identify 81 nonvolatile memory chips. In some implementations in which each of patterns of chip enable address signals generated by using four voltage levels identifies one nonvolatile memory chip, four chip enable signals may identify 256 nonvolatile memory chips.

That is, assuming that the number of pads is identically maintained, when chip enable address signals each having more voltage levels are used, the number of nonvolatile memory chips which the storage controller 120 is capable of identifying may increase.

Likewise, when each chip enable signal identifies one nonvolatile memory chip, 16 chip enable address signals may be required to identify 16 nonvolatile memory chips. When chip enable address signals each having two voltage levels are used, four chip enable address signals may be required to identify 16 nonvolatile memory chips.

When chip enable address signals each having three voltage levels are used, three chip enable address signals may be required to identify 16 nonvolatile memory chips. When chip enable address signals each having four voltage levels are used, two chip enable address signals may be required to identify 16 nonvolatile memory chips.

That is, when chip enable signals each having more voltage levels are used to identify the same number of nonvolatile memory chips, the number of pads of chip enable address signals required in each of the storage controller 120 and the nonvolatile memory chips may decrease.

The four voltage levels of the first to (M-1)-th chip enable address signals CEA[1:M-1], that is, the power supply voltage VCC, the data communication power supply voltage VCCQ, the channel communication power supply voltage VCCQL, and the ground voltage VSS may be voltages which are supplied from the storage controller 120 to the first to N-th nonvolatile memory chips 110_1 to 110_N of the nonvolatile memory device 110. Without needing to generate a separate voltage level in the first to N-th nonvolatile memory chips 110_1 to 110_N and without needing to receive a separate voltage from the storage controller 120, the first to N-th nonvolatile memory chips 110_1 to 110_N may identify the levels of the first to (M-1)-th chip enable address signals CEA[1:M-1] by using the power supply voltage VCC, the data communication power supply voltage VCCQ, the channel communication power supply voltage VCCQL, and the ground voltage VSS which are supplied from the storage controller 120.

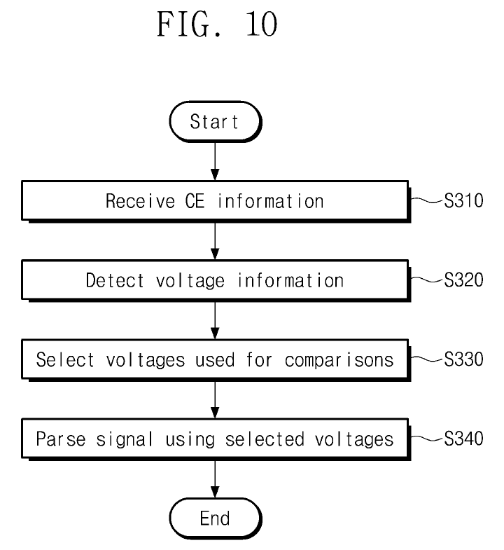

FIG. 7 illustrates an example of some circuits of the storage controller 120 according to some implementations of the present disclosure. Referring to FIG. 7, the storage controller 120 may include a multiplexer MUX which is connected to a k-th chip enable address pad P_CEAk configured to transfer a k-th chip enable address signal (e.g., CEAk) (k being a positive integer smaller than M).

The multiplexer MUX may receive the power supply voltage VCC, the data communication power supply voltage VCCQ, the channel communication power supply voltage VCCQL, and the ground voltage VSS. The multiplexer MUX may receive a selection signal corresponding to the k-th chip enable address signal CEAk from the chip address generator CAG. In response to the selection signal corresponding to the k-th chip enable address signal CEAk, the multiplexer MUX may output one of the power supply voltage VCC, the data communication power supply voltage VCCQ, the channel communication power supply voltage VCCQL, and the ground voltage VSS to the k-th chip enable address pad P_CEAk.

In some implementations, a pool of voltages which the multiplexer MUX is capable of selecting may be modified or applied from the example illustrated in FIG. 7. For example, as described with reference to FIG. 5, the pool of the voltages which the multiplexer MUX is capable of selecting may include the power supply voltage VCC, the data communication power supply voltage VCCQ, and the ground voltage VSS. In some implementations, the pool of the voltages which the multiplexer MUX is capable of selecting may include voltages (or some of the voltages) which the storage controller 120 supplies to the first to N-th nonvolatile memory chips 110_1 to 110_N of the nonvolatile memory device 110.

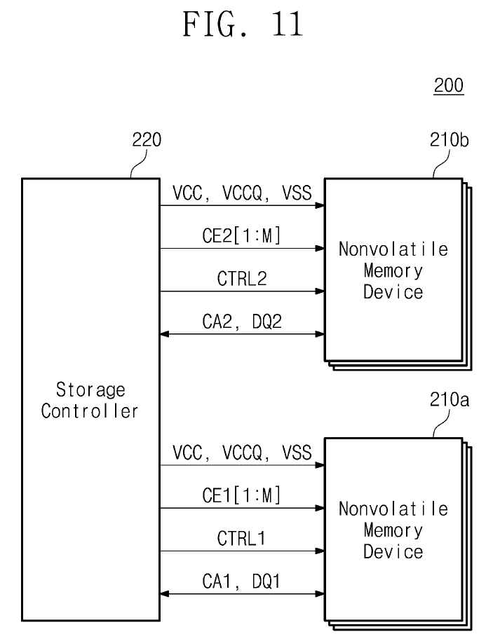

FIG. 8 illustrates an example of some circuits of the first to N-th nonvolatile memory chips 110_1 to 110_N of the nonvolatile memory device 110 according to some implementations of the present disclosure. In some implementations, an example of some circuits of the chip address parser CAP is illustrated in FIG. 8.

Referring to FIG. 8, the chip address parser CAP of each of the first to N-th nonvolatile memory chips 110_1 to 110_N of the nonvolatile memory device 110 may include comparators COMP and a determiner DET which are connected to the k-th chip enable address pad P_CEAk configured to transfer a k-th chip enable address signal (e.g., CEAk) (k being a positive integer smaller than M).

The comparators COMP may receive voltages which are generated as voltages of the k-th chip enable address signal CEAk. For example, when the k-th chip enable address signal CEAk is generated to have one of the power supply voltage VCC, the data communication power supply voltage VCCQ, the channel communication power supply voltage VCCQL, and the ground voltage VSS, the comparators COMP may receive the power supply voltage VCC, the data communication power supply voltage VCCQ, the channel communication power supply voltage VCCQL, and the ground voltage VSS.

For example, each of the first to N-th nonvolatile memory chips 110_1 to 110_N of the nonvolatile memory device 110 may include a power circuit configured to receive the power supply voltage VCC, the data communication power supply voltage VCCQ, the channel communication power supply voltage VCCQL, and the ground voltage VSS from the storage controller 120. The power circuit may supply the power supply voltage VCC, the data communication power supply voltage VCCQ, the channel communication power supply voltage VCCQL, and the ground voltage VSS to components of a nonvolatile memory chip and to the comparators COMP.

The comparators COMP may perform comparison with the level of the k-th chip enable address signal CEAk by using the power supply voltage VCC, the data communication power supply voltage VCCQ, the channel communication power supply voltage VCCQL, and the ground voltage VSS. The determiner DET may identify the level of the k-th chip enable address signal CEAk depending on a comparison result of the comparators COMP.

For example, the power supply voltage VCC may be higher than the data communication power supply voltage VCCQ. The data communication power supply voltage VCCQ may be higher than the channel communication power supply voltage VCCQL. The channel communication power supply voltage VCCQL may be higher than the ground voltage VSS.

When the comparison result of the comparators COMP indicates that the level of the k-th chip enable address signal CEAk is higher than the data communication power supply voltage VCCQ, the determiner DET may identify the level of the k-th chip enable address signal CEAk as the power supply voltage VCC. When the comparison result of the comparators COMP indicates that the level of the k-th chip enable address signal CEAk is lower than the channel communication power supply voltage VCCQL, the determiner DET may identify the level of the k-th chip enable address signal CEAk as the ground voltage VSS.

When the comparison result of the comparators COMP indicates that the level of the k-th chip enable address signal CEAk is higher than the channel communication power supply voltage VCCQL and is lower than the power supply voltage VCC, the determiner DET may identify the level of the k-th chip enable address signal CEAk as the data communication power supply voltage VCCQ. When the comparison result of the comparators COMP indicates that the level of the k-th chip enable address signal CEAk is lower than the data communication power supply voltage VCCQ and is higher than the ground voltage VSS, the determiner DET may identify the level of the k-th chip enable address signal CEAk as the channel communication power supply voltage VCCQL.

In some implementations, a pool of voltages which the comparators COMP are capable of comparing may be modified or applied from the example illustrated in FIG. 8. For example, as described with reference to FIG. 5, the pool of the voltages which the comparators COMP are capable of comparing may include the power supply voltage VCC, the data communication power supply voltage VCCQ, and the ground voltage VSS. In some implementations, the pool of the voltages which the comparators COMP are capable of comparing may include voltages (or some of the voltages) which the storage controller 120 supplies to the first to N-th nonvolatile memory chips 110_1 to 110_N of the nonvolatile memory device 110.

In some implementations, the first to N-th nonvolatile memory chips 110_1 to 110_N of the nonvolatile memory device 110 may independently identify the first to (M-1)-th chip enable address signals CEA[1:M-1] by using the voltages supplied from the storage controller 120. Accordingly, without signal lines and pads for supplying a voltage for identification of the first to (M-1)-th chip enable address signals CEA[1:M-1], the first to N-th nonvolatile memory chips 110_1 to 110_N of the nonvolatile memory device 110 may identify the level of the symbol of each of the first to (M-1)-th chip enable address signals CEA[1:M-1].

FIG. 9 illustrates an operation method of the storage device 100 according to some implementations of the present disclosure. Referring to FIGS. 1, 2, and 9, in operation S210, the storage device 100 may receive chip enable (CE) information.

In some implementations, the storage controller 120 may request the chip enable information from the first to N-th nonvolatile memory chips 110_1 to 110_N of the nonvolatile memory device 110 and may receive the chip enable information from each of the first to N-th nonvolatile memory chips 110_1 to 110_N. For example, the storage controller 120 may receive information about whether the first to N-th nonvolatile memory chips 110_1 to 110_N support operation modes associated with manners in which the first to N-th nonvolatile memory chips 110_1 to 110_N process the first to M-th chip enable signals CE[1:M], from the first to N-th nonvolatile memory chips 110_1 to 110_N as the chip enable information. The storage controller 120 may determine an operation mode associated with the first to M-th chip enable signals CE[1:M], based on the chip enable information received from the first to N-th nonvolatile memory chips 110_1 to 110_N. The storage controller 120 may transmit information of the determined operation mode to the first to N-th nonvolatile memory chips 110_1 to 110_N.

In some implementations, the first to N-th nonvolatile memory chips 110_1 to 110_N of the nonvolatile memory device 110 may receive the information about the operation mode from the storage controller 120 as the chip enable information. For example, the chip enable information may include information indicating one of the operation modes which each of the first to N-th nonvolatile memory chips 110_1 to 110_N supports.

In some implementations, in operation S220, the storage device 100 may determine whether the chip enable information indicates a first operation mode. When the first to N-th nonvolatile memory chips 110_1 to 110_N support the first operation mode, the storage controller 120 may receive information indicating that the first operation mode is supported, from the first to N-th nonvolatile memory chips 110_1 to 110_N as the chip enable information and may transmit information indicating the first operation mode to the first to N-th nonvolatile memory chips 110_1 to 110_N as the chip enable information.

When the first operation mode is selected, in operation S230, the storage device 100 may enter the first operation mode. The first operation mode may be a bit allocation mode. For example, the first to M-th chip enable signals CE[1:M] may respectively correspond to the first to N-th nonvolatile memory chips 110_1 to 110_N. When one of the first to M-th chip enable signals CE[1:M] is activated, the remaining chip enable signals may be deactivated. A nonvolatile memory chip corresponding to the activated chip enable signal from among the first to N-th nonvolatile memory chips 110_1 to 110_N may be activated, and nonvolatile memory chips corresponding to deactivated chip enable signals may be deactivated.

The activated nonvolatile memory chip may identify and communicate the control signals CTRL, the command and address CA, and the data DQ as a valid signal. The deactivated nonvolatile memory chips may identify the control signals CTRL, the command and address CA, and the data DQ as invalid signals and may ignore the control signals CTRL, the command and address CA, and the data DQ.

When the chip enable information does not indicate the first operation mode, in operation S240, the storage device 100 may determine whether the chip enable information indicates a second operation mode. When the first to N-th nonvolatile memory chips 110_1 to 110_N support the second operation mode, the storage controller 120 may receive information indicating that the second operation mode is supported, from the first to N-th nonvolatile memory chips 110_1 to 110_N as the chip enable information and may transmit information indicating the second operation mode to the first to N-th nonvolatile memory chips 110_1 to 110_N as the chip enable information.

When the second operation mode is selected, in operation S250, the storage device 100 may enter the second operation mode. The second operation mode may be a binary reduced mode described with reference to FIG. 3. For example, the first to M-th chip enable signals CE[1:M] may be used as the reduced chip enable signal CER and the first to (M-1)-th chip enable address signals CEA[1:M-1]. The storage controller 120 may generate the first to (M-1)-th chip enable address signals CEA[1:M-1] by using two voltage levels including the data communication power supply voltage VCCQ and the ground voltage VSS.

Patterns of the voltage levels of the first to (M-1)-th chip enable address signals CEA[1:M-1] may respectively correspond to the first to N-th nonvolatile memory chips 110_1 to 110_N. When the voltage levels of the first to (M-1)-th chip enable address signals CEA[1:M-1] has one pattern, a nonvolatile memory chip corresponding to the one pattern may be activated, and the remaining nonvolatile memory chips may be deactivated.

The activated nonvolatile memory chip may identify and communicate the control signals CTRL, the command and address CA, and the data DQ as a valid signal. The deactivated nonvolatile memory chips may identify the control signals CTRL, the command and address CA, and the data DQ as invalid signals and may ignore the control signals CTRL, the command and address CA, and the data DQ.

When the first to N-th nonvolatile memory chips 110_1 to 110_N support a third operation mode, the storage controller 120 may receive information indicating that the third operation mode is supported, from the first to N-th nonvolatile memory chips 110_1 to 110_N as the chip enable information and may transmit information indicating the third operation mode to the first to N-th nonvolatile memory chips 110_1 to 110_N as the chip enable information.

In the storage device 100 supporting one of the first operation mode, the second operation mode, and the third operation mode, when the first operation mode and the second operation mode are not selected, the third operation mode may be selected. In operation S260, the storage device 100 may enter the third operation mode. The third operation mode may be a multi-reduced mode described with reference to FIGS. 5, and FIG.6. For example, the first to M-th chip enable signals CE[1:M] may be used as the reduced chip enable signal CER and the first to (M-1)-th chip enable address signals CEA[1:M-1]. The storage controller 120 may generate the first to (M-1)-th chip enable address signals CEA[1:M-1] by using at least three voltages including the power supply voltage VCC, the data communication power supply voltage VCCQ, and the ground voltage VSS (or further including the channel communication power supply voltage VCCQL).

Patterns of the voltage levels of the first to (M-1)-th chip enable address signals CEA[1:M-1] may respectively correspond to the first to N-th nonvolatile memory chips 110_1 to 110_N. When the voltage levels of the first to (M-1)-th chip enable address signals CEA[1:M-1] has one pattern, a nonvolatile memory chip corresponding to the one pattern may be activated, and the remaining nonvolatile memory chips may be deactivated.

The activated nonvolatile memory chip may identify and communicate the control signals CTRL, the command and address CA, and the data DQ as a valid signal. The deactivated nonvolatile memory chips may identify the control signals CTRL, the command and address CA, and the data DQ as invalid signals and may ignore the control signals CTRL, the command and address CA, and the data DQ.

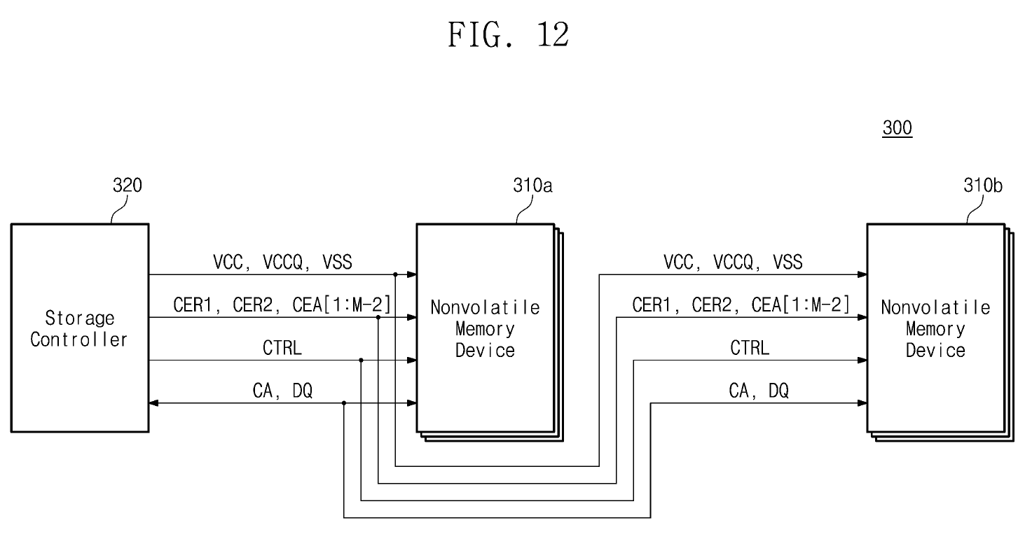

FIG. 10 illustrates an application example of an operation method of the storage device 100 according to some implementations of the present disclosure. Referring to FIGS. 1, 2, and 10, in operation S310 the nonvolatile memory device 110 may receive the chip enable (CE) information from the storage controller 120. For example, the storage controller 120 may transmit voltage information as the chip enable information to the nonvolatile memory device 110.

The storage controller 120 may provide a plurality of voltages to the first to N-th nonvolatile memory chips 110_1 to 110_N of the nonvolatile memory device 110. The storage controller 120 may select voltages, which are used to generate the first to (M-1)-th chip enable address signals CEA[1:M-1], from among the plurality of voltages. The storage controller 120 may transmit information of the selected voltages as the chip enable information, to the first to N-th nonvolatile memory chips 110_1 to 110_N of the nonvolatile memory device 110.

In operation S320, the first to N-th nonvolatile memory chips 110_1 to 110_N of the nonvolatile memory device 110 may detect voltage information from the chip enable information. In some implementations, the voltage information may be received together with information indicating the third operation mode (e.g., the multi-reduced mode). The voltage information may include information indicating voltages which are used to generate the first to (M-1)-th chip enable address signals CEA[1:M-1]. Alternatively, when all the voltages which the storage controller 120 supplies to the first to N-th nonvolatile memory chips 110_1 to 110_N of the nonvolatile memory device 110 are used to generate the first to (M-1)-th chip enable address signals CEA[1:M-1], the voltage information may indicate a default value.

In operation S330, the first to N-th nonvolatile memory chips 110_1 to 110_N of the nonvolatile memory device 110 may select voltages which are used for comparisons. For example, the comparators COMP (refer to FIG. 8) may include comparators configured to compare the received voltages and the k-th chip enable address signal CEAk, and each of the comparators may be selectively activated or deactivated based on the voltage information. The determiner DET may determine the level of the k-th chip enable address signal CEAk depending on outputs of the activated comparators.

As another example, the comparators COMP may maintain an active state, and the determiner DET may determine the level of the k-th chip enable address signal CEAk by selectively using the outputs of the comparators COMP. The determiner DET may be configured to determine the level of the k-th chip enable address signal CEAk by using outputs of comparators corresponding to the voltage information.

In operation S340, the first to N-th nonvolatile memory chips 110_1 to 110_N of the nonvolatile memory device 110 may parse a signal by using the selected voltages. For example, the determiner DET may determine the level of the k-th chip enable address signal CEAk. The first to N-th nonvolatile memory chips 110_1 to 110_N of the nonvolatile memory device 110 may parse and the identify a pattern of levels of the first to (M-1)-th chip enable address signals CEA[1:M-1].

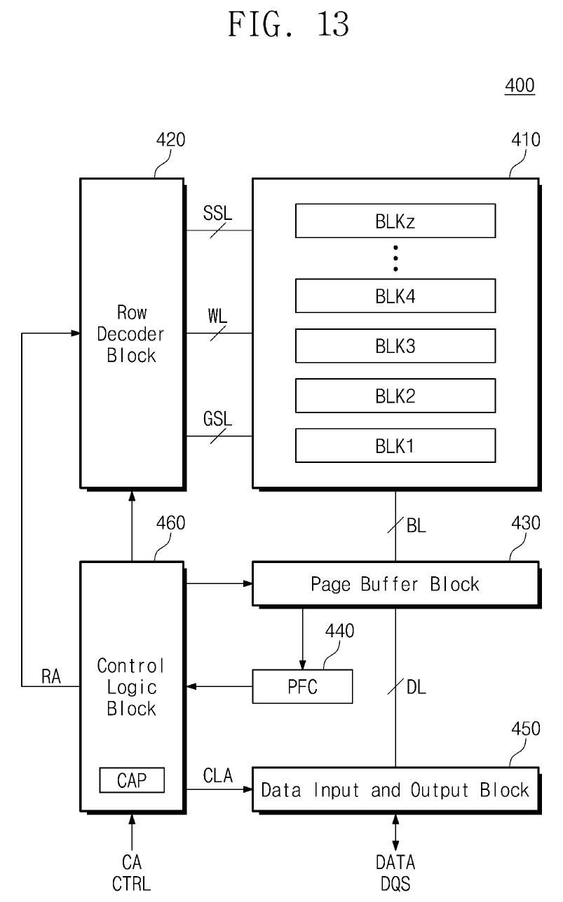

FIG. 11 illustrates a storage device 200 according to some implementations of the present disclosure. Referring to FIG. 11, the storage device 200 may include a first nonvolatile memory device 210a, a second nonvolatile memory device 210b, and a storage controller 220.

Each of the first nonvolatile memory device 210a and the second nonvolatile memory device 210b may include a plurality of nonvolatile memory devices, for example, a plurality of nonvolatile memory chips. The plurality of nonvolatile memory chips of each of the first nonvolatile memory device 210a and the second nonvolatile memory device 210b may be controlled by the storage controller 220.

The storage controller 220 may supply voltages (or a power) to the plurality of nonvolatile memory chips of each of the first nonvolatile memory device 210a and the second nonvolatile memory device 210b in common. For example, the storage controller 220 may supply the power supply voltage VCC, the data communication power supply voltage VCCQ, and the ground voltage VSS to the plurality of nonvolatile memory chips of each of the first nonvolatile memory device 210a and the second nonvolatile memory device 210b in common. Alternatively, as described with reference to FIG. 6, the storage controller 220 may supply the power supply voltage VCC, the data communication power supply voltage VCCQ, the channel communication power supply voltage VCCQL, and the ground voltage VSS to the plurality of nonvolatile memory chips of each of the first nonvolatile memory device 210a and the second nonvolatile memory device 210b in common.

The storage controller 220 may transmit a first type of first to M-th chip enable signals CE1[1:M] to the plurality of nonvolatile memory chips of the first nonvolatile memory device 210a. In some implementations, the first to M-th chip enable signals CE1[1:M] of the first type may be transferred through a first type of chip enable signal lines connected in common between the storage controller 220 and the plurality of nonvolatile memory chips of the first nonvolatile memory device 210a.

The storage controller 220 may transmit a second type of first to M-th chip enable signals CE2[1:M] to the plurality of nonvolatile memory chips of the second nonvolatile memory device 210b. In some implementations, the first to M-th chip enable signals CE2[1:M] of the second type may be transferred through a second type of chip enable signal lines connected in common between the storage controller 220 and the plurality of nonvolatile memory chips of the second nonvolatile memory device 210b. The second-type chip enable signal lines may be separated from the first-type chip enable signal lines.

The storage controller 220 may independently identify and select the plurality of nonvolatile memory chips of the first nonvolatile memory device 210a by using the first to M-th chip enable signals CE1[1:M] of the first type. For example, as described with reference to FIG. 9, the first to M-th chip enable signals CE1[1:M] of the first type may be used to identify the plurality of nonvolatile memory chips of the first nonvolatile memory device 210a in one operation mode among the bit allocation mode being the first operation mode, the binary reduced mode being the second operation mode, and the multi-reduced mode being the third operation mode.

The storage controller 220 may independently identify and select the plurality of nonvolatile memory chips of the second nonvolatile memory device 210b by using the first to M-th chip enable signals CE2[1:M] of the second type. For example, as described with reference to FIG. 9, the first to M-th chip enable signals CE2[1:M] of the second type may be used to identify the plurality of nonvolatile memory chips of the second nonvolatile memory device 210b in one operation mode among the bit allocation mode being the first operation mode, the binary reduced mode being the second operation mode, and the multi-reduced mode being the third operation mode. In some implementations, an operation mode in which the first to M-th chip enable signals CE2[1:M] of the second type are used may be the same as or different from an operation mode in which the first to M-th chip enable signals CE1[1:M] of the first type are used.

The storage controller 220 may transmit a first type of control signals CTRL1 to the plurality of nonvolatile memory chips of the first nonvolatile memory device 210a. In some implementations, the control signals CTRL1 of the first type may be transferred through a first type of control signal lines connected in common between the storage controller 220 and the plurality of nonvolatile memory chips of the first nonvolatile memory device 210a.

The storage controller 220 may transmit a second type of control signals CTRL2 to the plurality of nonvolatile memory chips of the second nonvolatile memory device 210b. In some implementations, the control signals CTRL2 of the second type may be transferred through a second type of control signal lines connected in common between the storage controller 220 and the plurality of nonvolatile memory chips of the second nonvolatile memory device 210b. The second-type control signal lines may be separated from the first-type control signal lines.

The storage controller 220 may control operations of the plurality of nonvolatile memory chips of the first nonvolatile memory device 210a, for example, an operation of a nonvolatile memory chip selected by the first to M-th chip enable signals CE1[1:M] of the first type by using the control signals CTRL1 of the first type. The storage controller 220 may control operations of the plurality of nonvolatile memory chips of the second nonvolatile memory device 210b, for example, an operation of a nonvolatile memory chip selected by the first to M-th chip enable signals CE2[1:M] of the second type by using the control signals CTRL2 of the second type.

The storage controller 220 may communicate a first type of command and address CA1 and a first type of data DQ1 with the plurality of nonvolatile memory chips of the first nonvolatile memory device 210a. In some implementations, the command and address CA1 of the first type may be transferred through a first type of command and address signal lines connected in common between the storage controller 220 and the plurality of nonvolatile memory chips of the first nonvolatile memory device 210a. The data DQ1 of the first type may be transferred through a first type of data signal lines connected in common between the storage controller 220 and the plurality of nonvolatile memory chips of the first nonvolatile memory device 210a.

The storage controller 220 may communicate a second type of command and address CA2 and a second type of data DQ2 with the plurality of nonvolatile memory chips of the second nonvolatile memory device 210b. In some implementations, the command and address CA2 of the second type may be transferred through a second type of command and address signal lines connected in common between the storage controller 220 and the plurality of nonvolatile memory chips of the second nonvolatile memory device 210b. The data DQ2 of the second type may be transferred through a second type of data signal lines connected in common between the storage controller 220 and the plurality of nonvolatile memory chips of the second nonvolatile memory device 210b. The second-type command and address signal lines may be separated from the first-type command and address signal lines. The second-type data signal lines may be separated from the first-type data signal lines.

In some implementations, the first-type command and address signal lines and the first-type data signal lines may be signal lines separated from each other. That is, the command and address CA1 of the first type and the data DQ1 of the first type may be transferred through different signal lines. As another example, the first-type command and address signal lines and the first-type data signal lines may be the same signal lines. That is, the command and address CA1 of the first type and the data DQ1 of the first type may be transferred through the same signal lines.

Likewise, the second-type command and address signal lines and the second-type data signal lines may be signal lines separated from each other. That is, the command and address CA2 of the second type and the data DQ2 of the second type may be transferred through different signal lines. As another example, the second-type command and address signal lines and the second-type data signal lines may be the same signal lines. That is, the command and address CA2 of the second type and the data DQ2 of the second type may be transferred through the same signal lines.

In some implementations, the first-type command and address signal lines and the first-type data signal lines may be the same signal lines, and the second-type command and address signal lines and the second-type data signal lines may be the same signal lines. The first-type command and address signal lines and the first-type data signal lines may be the same signal lines, and the second-type command and address signal lines and the second-type data signal lines may be separated signal lines. The first-type command and address signal lines and the first-type data signal lines may be separated signal lines, and the second-type command and address signal lines and the second-type data signal lines may be the same signal lines.

In some implementations, the storage controller 220 may control the first nonvolatile memory device 210a and the second nonvolatile memory device 210b independently of each other. The storage controller 220 may communicate with the first nonvolatile memory device 210a and the second nonvolatile memory device 210b independently of each other

The storage controller 220 may use the first to M-th chip enable signals CE1[1:M] of the first type and the first to M-th chip enable signals CE2[1:M] of the second type independently of each other. For example, the storage controller 220 may be considered as being connected to the first nonvolatile memory device 210a through one channel and being connected to the second nonvolatile memory device 210b through another independent channel.

FIG. 12 illustrates a storage device 300 according to some implementations of the present disclosure. Referring to FIGS. 1 and 12, the storage device 300 may include a first nonvolatile memory device 310a, a second nonvolatile memory device 310b, and a storage controller 320.

Each of the first nonvolatile memory device 310a and the second nonvolatile memory device 310b may include a plurality of nonvolatile memory devices, for example, a plurality of nonvolatile memory chips. The plurality of nonvolatile memory chips of each of the first nonvolatile memory device 310a and the second nonvolatile memory device 310b may be controlled by the storage controller 320.

The storage controller 320 may supply voltages (or a power) to the plurality of nonvolatile memory chips of each of the first nonvolatile memory device 310a and the second nonvolatile memory device 310b in common. For example, the storage controller 320 may supply the power supply voltage VCC, the data communication power supply voltage VCCQ, and the ground voltage VSS to the plurality of nonvolatile memory chips of each of the first nonvolatile memory device 310a and the second nonvolatile memory device 310b in common. Alternatively, as described with reference to FIG. 6, the storage controller 320 may supply the power supply voltage VCC, the data communication power supply voltage VCCQ, the channel communication power supply voltage VCCQL, and the ground voltage VSS to the plurality of nonvolatile memory chips of each of the first nonvolatile memory device 310a and the second nonvolatile memory device 310b in common.

The storage controller 320 may transmit the first to M-th chip enable signals CE1[1:M] of the first type to the plurality of nonvolatile memory chips of the first nonvolatile memory device 310a. In some implementations, the first to M-th chip enable signals CE1[1:M] may be transferred through chip enable signal lines connected in common between the storage controller 320, the plurality of nonvolatile memory chips of the first nonvolatile memory device 310a, and the plurality of nonvolatile memory chips of the second nonvolatile memory device 310b.

The storage controller 320 may independently identify and select the plurality of nonvolatile memory chips of the first nonvolatile memory device 310a and the plurality of nonvolatile memory chips of the second nonvolatile memory device 310b by using the first to M-th chip enable signals CE1[1:M]. For example, the first to M-th chip enable signals CE[1:M] may be used as a first reduced chip enable signal CER1, a second reduced chip enable signal CER2, and first to (M-2)-th chip enable address signals CEA[1:M-2].

The first reduced chip enable signal CER1 may indicate the first nonvolatile memory device 310a. While the first reduced chip enable signal CER1 is activated, the plurality of nonvolatile memory chips of the first nonvolatile memory device 310a may refer to the first to (M-2)-th chip enable address signals CEA[1:M-2]. A nonvolatile memory chip corresponding to a pattern of the first to (M-2)-th chip enable address signals CEA[1:M-2] from among the plurality of nonvolatile memory chips of the first nonvolatile memory device 310a may identify and receive the control signals CTRL, the command and address CA, and the data DQ as a valid signal. Nonvolatile memory chips not corresponding to the pattern of the first to (M-2)-th chip enable address signals CEA[1:M-2] may identify the control signals CTRL, the command and address CA, and the data DQ as invalid signals and may ignore the control signals CTRL, the command and address CA, and the data DQ.

The second reduced chip enable signal CER2 may indicate the second nonvolatile memory device 310b. While the second reduced chip enable signal CER2 is activated, the plurality of nonvolatile memory chips of the second nonvolatile memory device 310b may refer to the first to (M-2)-th chip enable address signals CEA[1:M-2]. A nonvolatile memory chip corresponding to the pattern of the first to (M-2)-th chip enable address signals CEA[1:M-2] from among the plurality of nonvolatile memory chips of the second nonvolatile memory device 310b may identify and receive the control signals CTRL, the command and address CA, and the data DQ as a valid signal. Nonvolatile memory chips not corresponding to the pattern of the first to (M-2)-th chip enable address signals CEA[1:M-2] may identify the control signals CTRL, the command and address CA, and the data DQ as invalid signals and may ignore the control signals CTRL, the command and address CA, and the data DQ.

For example, as described with reference to FIG. 9, the first to (M-2)-th chip enable address signals CEA[1:M-2] may be used to identify the plurality of nonvolatile memory chips of each of the first nonvolatile memory device 310a and the second nonvolatile memory device 310b in one operation mode among the bit allocation mode being the first operation mode, the binary reduced mode being the second operation mode, and the multi-reduced mode being the third operation mode.

The storage controller 320 may transmit the control signals CTRL to the plurality of nonvolatile memory chips of the first nonvolatile memory device 310a. In some implementations, the control signals CTRL may be transferred through a first type of control signal lines connected in common between the storage controller 320, the plurality of nonvolatile memory chips of the first nonvolatile memory device 310a, and the plurality of nonvolatile memory chips of the second nonvolatile memory device 310b.

The storage controller 320 may control operations of the plurality of nonvolatile memory chips of each of the first nonvolatile memory device 310a and the second nonvolatile memory device 310b, for example, an operation of a nonvolatile memory chip selected by the first to M-th chip enable signals CE[1:M] by using the control signals CTRL.

The storage controller 320 may communicate the command and address CA and the data DQ with the plurality of nonvolatile memory chips of the first nonvolatile memory device 310a and the plurality of nonvolatile memory chips of the second nonvolatile memory device 310b. In some implementations, the command and address CA may be transferred through command and address signal lines connected in common between the storage controller 320, the plurality of nonvolatile memory chips of the first nonvolatile memory device 310a, and the plurality of nonvolatile memory chips of the second nonvolatile memory device 310b. The data DQ may be transferred through data signal lines connected in common between the storage controller 320, the plurality of nonvolatile memory chips of the first nonvolatile memory device 310a, and the plurality of nonvolatile memory chips of the second nonvolatile memory device 310b.

In some implementations, the command and address signal lines and the data signal lines may be signal lines separated from each other. That is, the command and address CA and the data DQ may be transferred through different signal lines. As another example, the command and address signal lines and the data signal lines may be the same signal lines. That is, the command and address CA and the data DQ may be transferred through the same signal lines.

In some implementations, the storage controller 320 may select and control one of the first nonvolatile memory device 310a and the second nonvolatile memory device 310b. The storage controller 320 may alternately communicate with the first nonvolatile memory device 310a and the second nonvolatile memory device 310b. In some implementations, the first nonvolatile memory device 310a and the second nonvolatile memory device 310b may be considered as being connected to the storage controller 320 through the same channel. The first nonvolatile memory device 310a and the second nonvolatile memory device 310b may be considered as different pathways connected to the same channel.

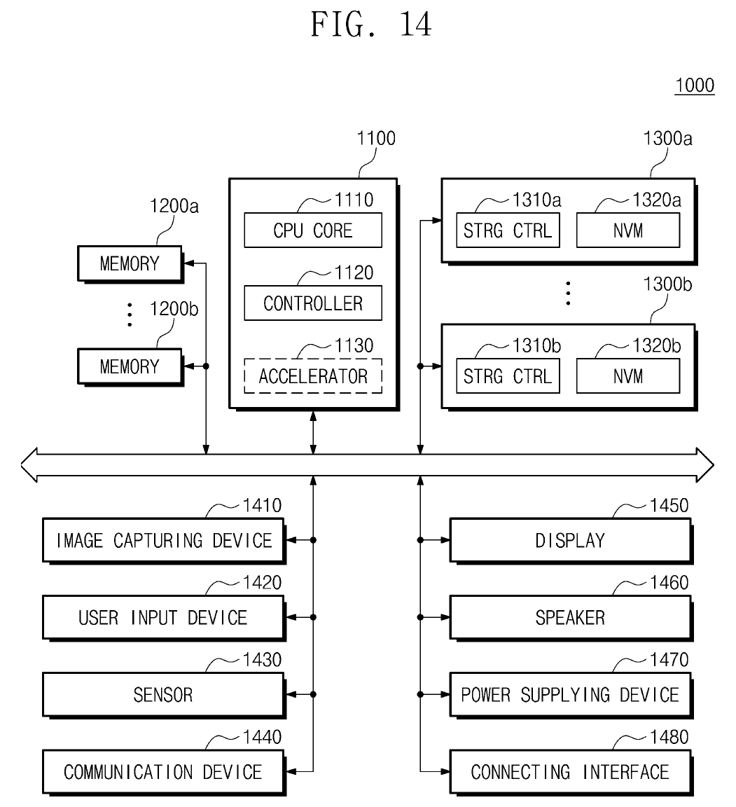

FIG. 13 is a block diagram illustrating a nonvolatile memory chip 400 according to some implementations of the present disclosure. Referring to FIGS. 1 and 13, the nonvolatile memory chip 400 includes a memory cell array 410, a row decoder block 420, a page buffer block 430, a pass/fail check block (PFC) 440, a data input and output block 450, and a control logic block 460.

The memory cell array 410 includes a plurality of memory blocks BLK1 to BLKz. Each of the memory blocks BLK1 to BLKz includes a plurality of memory cells. Each of the memory blocks BLK1 to BLKz may be connected to the row decoder block 420 through at least one ground selection line GSL, word lines WL, and at least one string selection line SSL. Some of the word lines WL may be used as dummy word lines. Each of the memory blocks BLK1 to BLKz may be connected to the page buffer block 430 through a plurality of bit lines BL. The plurality of memory blocks BLK1 to BLKz may be connected in common to the plurality of bit lines BL.

In some implementations, each of the plurality of memory blocks BLK1 to BLKz may correspond to a unit of the erase operation. Memory cells belonging to each memory block may be erased at the same time. As another example, each memory block may be divided into a plurality of sub-blocks. Each of the plurality of sub-blocks may correspond to a unit of the erase operation.

The row decoder block 420 is connected to the memory cell array 410 through the ground selection lines GSL, the word lines WL, and the string selection lines SSL. The row decoder block 420 operates under control of the control logic block 460.

The row decoder block 420 may decode a row address RA received from the control logic block 460 and may control voltages to be applied to the string selection lines SSL, the word lines WL, and the ground selection lines GSL based on the decoded row address.

The page buffer block 430 is connected to the memory cell array 410 through the plurality of bit lines BL. The page buffer block 430 is connected to the data input and output block 450 through a plurality of data lines DL. The page buffer block 430 operates under control of the control logic block 460.

In the program operation, the page buffer block 430 may store data to be written in memory cells. The page buffer block 430 may apply voltages to the plurality of bit lines BL based on the stored data. In the read operation or in the verify read operation that is performed in the program operation or the erase operation, the page buffer block 430 may sense voltages of the bit lines BL and may store a sensing result.

In the verify read operation associated with the program operation or the erase operation, the pass/fail check block 440 may verify the sensing result of the page buffer block 430. For example, in the verify read operation which is performed in the program operation, the pass/fail check block 440 may count the number of values (e.g., the number of 0s) corresponding to on-cells which are not programmed to a target threshold voltage or higher.

In the verify read operation which is performed in the erase operation, the pass/fail check block 440 may count the number of values (e.g., the number of 1s) corresponding to off-cells which are not erased to a target threshold voltage or lower. When a counting result is greater than or equal to a threshold value, the pass/fail check block 440 may output a fail signal to the control logic block 460. When the counting result is smaller than the threshold value, the pass/fail check block 440 may output a pass signal to the control logic block 460. Depending on the verification result of the pass/fail check block 440, a program loop of the program operation may be further performed, or an erase loop of the erase operation may be further performed.

The data input and output block 450 is connected to the page buffer block 430 through the plurality of data lines DL. The data input and output block 450 may receive a column address CLA from the control logic block 460. The data input and output block 450 may output the data DQ read by the page buffer block 430 to an external device (e.g., the storage controller 120, 220, or 320) depending on the column address CLA. The data input and output block 450 may transfer the data DQ received from the external device (e.g., the storage controller 120, 220, or 320) to the page buffer block 430, based on the column address CLA.

The control logic block 460 may receive the command and address CA, the control signals CTRL, and the first to M-th chip enable signals CE[1:M] from the external device (e.g., the storage controller 120, 220, or 320). In some implementations, the control logic block 460 may include the chip address parser CAP described with reference to FIGS. 1 and 2. The chip address parser CAP may parse and identify the first to M-th chip enable signals CE[1:M] in one operation mode among the bit allocation mode being the first operation mode, the binary reduced mode being the second operation mode, and the multi-reduced mode being the third operation mode.

When activated by the first to M-th chip enable signals CE[1:M], the control logic block 460 may parse a command of the command and address CA. The control logic block 460 may control the nonvolatile memory chip 400 depending on the parsed command. The control logic block 460 may extract the row address RA and the column address CLA by decoding an address of the command and address CA. The control logic block 460 may transfer the row address RA to the row decoder block 420 and may transfer the column address CLA to the data input and output block 450.

In some implementations, signal lines of the command and address CA may be the same as signal lines of the data DQ. The command and address CA and the data DQ received through the same signal lines may be transferred to the control logic block 460 and the data input and output block 450 through one global buffer. As another example, in some implementations, the signal lines of the command and address CA may be different from the signal lines of the data DQ. The command and address CA may be transferred to the control logic block 460 through a command and address buffer, and the data DQ may be transferred to the data input and output block 450 through a data buffer.

In some implementations, the nonvolatile memory chip 400 may communicate the data DQ with the external device (e.g., the storage controller 120, 220, or 320) in synchronization with a data strobe signal (e.g., DQS). The nonvolatile memory chip 400 may receive the data strobe signal DQS and the data DQ from the external device (e.g., the storage controller 120, 220, or 320) and may store the data DQ in synchronization with the data strobe signal DQS. The nonvolatile memory chip 400 may receive a signal (e.g., a read enable signal RE) toggling as one of the control signals CTRL from the external device (e.g., the storage controller 120, 220, or 320). The nonvolatile memory chip 400 may generate the data strobe signal DQS from the toggling signal and may transmit the data strobe signal DQS and the data DQ to the external device (e.g., the storage controller 120, 220, or 320).

In some implementations, the nonvolatile memory chip 400 may be manufactured in a bonding method. The memory cell array 410 may be manufactured by using a first wafer, and the row decoder block 420, the page buffer block 430, the pass/fail check block 440, the data input and output block 450, and the control logic block 460 may be manufactured by using a second wafer. The nonvolatile memory chip 400 may be implemented by coupling the first wafer and the second wafer such that an upper surface of the first wafer and an upper surface of the second wafer face each other.

As another example, the nonvolatile memory chip 400 may be manufactured in a cell over periphery (COP) method. A peripheral circuit including the row decoder block 420, the page buffer block 430, the pass/fail check block 440, the data input and output block 450, and the control logic block 460 may be implemented on a substrate. The memory cell array 410 may be implemented over the peripheral circuit. The peripheral circuit and the memory cell array 410 may be connected by using the through vias.

FIG. 14 is a diagram of a system 1000 to which a storage device is applied, according to some implementations. The system 1000 of FIG. 14 may basically be a mobile system, such as a portable communication terminal (e.g., a mobile phone), a smartphone, a tablet personal computer (PC), a wearable device, a healthcare device, or an Internet of things (IOT) device. However, the system 1000 of FIG. 14 is not necessarily limited to the mobile system and may be a PC, a laptop computer, a server, a media player, or an automotive device (e.g., a navigation device).

Referring to FIG. 14, the system 1000 may include a main processor 1100, memories (e.g., 1200a and 1200b), and storage devices (e.g., 1300a and 1300b). In addition, the system 1000 may include at least one of an image capturing device 1410, a user input device 1420, a sensor 1430, a communication device 1440, a display 1450, a speaker 1460, a power supplying device 1470, and a connecting interface 1480.

The main processor 1100 may control all operations of the system 1000, more specifically, operations of other components included in the system 1000. The main processor 1100 may be implemented as a general-purpose processor, a dedicated processor, or an application processor.

The main processor 1100 may include at least one CPU core 1110 and further include a controller 1120 configured to control the memories 1200a and 1200b and/or the storage devices 1300a and 1300b. In some implementations, the main processor 1100 may further include an accelerator 1130, which is a dedicated circuit for a high-speed data operation, such as an artificial intelligence (AI) data operation. The accelerator 1130 may include a graphics processing unit (GPU), a neural processing unit (NPU) and/or a data processing unit (DPU) and be implemented as a chip that is physically separate from the other components of the main processor 1100.

The memories 1200a and 1200b may be used as main memory devices of the system 1000. Although each of the memories 1200a and 1200b may include a volatile memory, such as static random access memory (SRAM) and/or dynamic RAM (DRAM), each of the memories 1200a and 1200b may include non-volatile memory, such as a flash memory, phase-change RAM (PRAM) and/or resistive RAM (RRAM). The memories 1200a and 1200b may be implemented in the same package as the main processor 1100.

The storage devices 1300a and 1300b may serve as non-volatile storage devices configured to store data regardless of whether power is supplied thereto and have larger storage capacity than the memories 1200a and 1200b. The storage devices 1300a and 1300b may respectively include storage controllers (STRG CTRL) 1310a and 1310b and NVMs (Non-Volatile Memories) 1320a and 1320b configured to store data via the control of the storage controllers 1310a and 1310b. Although the NVMs 1320a and 1320b may include flash memories having a two-dimensional (2D) structure or a three-dimensional (3D) V-NAND structure, the NVMs 1320a and 1320b may include other types of NVMs, such as PRAM and/or RRAM.

The storage devices 1300a and 1300b may be physically separated from the main processor 1100 and included in the system 1000 or implemented in the same package as the main processor 1100. In addition, the storage devices 1300a and 1300b may have types of solid-state devices (SSDs) or memory cards and be removably combined with other components of the system 1000 through an interface, such as the connecting interface 1480 that will be described below. The storage devices 1300a and 1300b may be devices to which a standard protocol, such as a universal flash storage (UFS), an embedded multi-media card (eMMC), or a non-volatile memory express (NVMe), is applied, without being limited thereto.

The image capturing device 1410 may capture still images or moving images. The image capturing device 1410 may include a camera, a camcorder, and/or a webcam.

The user input device 1420 may receive various types of data input by a user of the system 1000 and include a touch pad, a keypad, a keyboard, a mouse, and/or a microphone.

The sensor 1430 may detect various types of physical quantities, which may be obtained from the outside of the system 1000 and convert the detected physical quantities into electric signals. The sensor 1430 may include a temperature sensor, a pressure sensor, an illuminance sensor, a position sensor, an acceleration sensor, a biosensor, and/or a gyroscope sensor.

The communication device 1440 may transmit and receive signals between other devices outside the system 1000 according to various communication protocols. The communication device 1440 may include an antenna, a transceiver, and/or a modem.

The display 1450 and the speaker 1460 may serve as output devices configured to respectively output visual information and auditory information to the user of the system 1000.

The power supplying device 1470 may appropriately convert power supplied from a battery embedded in the system 1000 and/or an external power source and supply the converted power to each of components of the system 1000.

The connecting interface 1480 may provide connection between the system 1000 and an external device, which is connected to the system 1000 and capable of transmitting and receiving data to and from the system 1000. The connecting interface 1480 may be implemented by using various interface schemes, such as advanced technology attachment (ATA), serial ATA (SATA), external SATA (e-SATA), small computer small interface (SCSI), serial attached SCSI (SAS), peripheral component interconnection (PCI), PCI express (PCIe), NVMe, IEEE 1394, a universal serial bus (USB) interface, a secure digital (SD) card interface, a multi-media card (MMC) interface, an eMMC interface, a UFS interface, an embedded UFS (eUFS) interface, and a compact flash (CF) card interface.

In some implementations, the storage device 100, 200, or 300 described with reference to FIGS. 1 to 13 may be implemented with at least one of the storage devices 1300a and 1300b. At least one of the storage devices 1300a and 1300b may operate in one operation mode among the bit allocation mode being the first operation mode, the binary reduced mode being the second operation mode, and the multi-reduced mode being the third operation mode. In the multi-reduced mode being the third operation mode, at least one of the storage devices 1300a and 1300b may independently generate chip enable address signals by using one of at least three voltages.

In the above implementations, components according to the present disclosure are described by using the terms “first”, “second”, “third”, etc. However, the terms “first”, “second”, “third”, etc. may be used to distinguish components from each other and do not limit the present disclosure. For example, the terms “first”, “second”, “third”, etc. do not involve an order or a numerical meaning of any form.

In the above implementations, components according to implementations of the present disclosure are referenced by using blocks. The blocks may be implemented with various hardware devices, such as an integrated circuit, an application specific IC (ASIC), a field programmable gate array (FPGA), and a complex programmable logic device (CPLD), firmware driven in hardware devices, software such as an application, or a combination of a hardware device and software. Also, the blocks may include circuits implemented with semiconductor elements in an integrated circuit, or circuits enrolled as an intellectual property (IP).

According to implementations of the present disclosure, a storage controller and a nonvolatile memory device may generate a chip enable signal for identifying nonvolatile memory devices by using one of at least three voltages. Accordingly, a storage device with the reduced area and complexity and improved expandability in association with a chip enable signal, an operation method of the storage device, and a nonvolatile memory device of the storage device are provided.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been described with reference to implementations thereof, it will be apparent to those of ordinary skill in the art that various changes and modifications may be made thereto without departing from the spirit and scope of the present disclosure as set forth in the following claims.

What is claimed is:

1. A storage device comprising
a plurality of nonvolatile memory devices, and
a storage controller configured to:
select at least a first nonvolatile memory device of the plurality of nonvolatile memory devices based on control of a plurality of chip enable signals to be transferred to the plurality of nonvolatile memory devices;
use a first chip enable signal of the plurality of chip enable signals as a reduced chip enable signal and remaining chip enable signals of the plurality of chip enable signals as chip enable address signals;
select the at least first nonvolatile memory device of the plurality of nonvolatile memory devices based on activation of the reduced chip enable signal and control of the chip enable address signals; and
generate each chip enable address signal of the chip enable address signals based on one of at least three voltage levels.

2. The storage device of claim 1, wherein the storage controller is configured to supply a plurality of voltages to the nonvolatile memory devices, and
wherein the plurality of voltages comprise the at least three voltage levels.

3. The storage device of claim 2, wherein the at least three voltage levels comprise a power supply voltage, a ground voltage, and a data communication power supply voltage.

4. The storage device of claim 2, wherein the plurality of voltages comprise at least four voltage levels, and the at least four voltage levels comprise a power supply voltage, a ground voltage, a data communication power supply voltage, and a channel communication power supply voltage.

5. The storage device of claim 1, wherein the storage controller is configured to operate in two different modes, wherein the two different modes comprise a first operation mode and a second operation mode,
wherein, in the first operation mode, the storage controller is configured to generate each chip enable address signal of the chip enable address signals based on one of two voltage levels of the first operation mode, and
wherein, in the second operation mode, the storage controller is configured to generate each chip enable address signal of the chip enable address signals based on one of the at least three voltage levels.

6. The storage device of claim 1, wherein the storage controller is configured to operate in two operation modes, wherein the two operation modes comprise a first operation mode and a second operation mode,
wherein, in the first operation mode, the storage controller is configured to select the first nonvolatile memory device of the plurality of nonvolatile memory devices based on activation of a first chip enable signal of the chip enable signals, and
wherein, in the second operation mode, the storage controller is configured to generate each chip enable address signal of the chip enable address signals based on one of the at least three voltage levels.

7. The storage device of claim 1, wherein the storage controller is configured to supply a plurality of voltages to the nonvolatile memory devices, and
wherein the storage controller is configured to select the at least three voltage levels among the plurality of voltages.

8. The storage device of claim 7, wherein the storage controller is configured to transmit selection information of the at least three voltage levels to the plurality of nonvolatile memory devices.

9. The storage device of claim 1, wherein each nonvolatile memory device of the plurality of nonvolatile memory devices is configured to:
receive the reduced chip enable signal and the chip enable address signals; and
determine that each of the chip enable address signals corresponds to a respective level of the at least three voltage levels, in response to activation of the reduced chip enable signal.

10. The storage device of claim 9, wherein each nonvolatile memory device of the plurality of nonvolatile memory devices is configured to determine whether to be activated based on a combination of levels of the chip enable address signals.

11. The storage device of claim 9, wherein each nonvolatile memory device of the plurality of nonvolatile memory devices is configured to receive a plurality of voltages from the storage controller; and
wherein the plurality of voltages comprises the at least three voltage levels.

12. The storage device of claim 1, wherein each nonvolatile memory device of the plurality of nonvolatile memory devices is configured to receive chip enable information from the storage controller,
wherein, based on the chip enable information indicating a first operation mode, each nonvolatile memory device of the plurality of nonvolatile memory devices is configured to determine that each chip enable address signal of the chip enable address signals corresponds to a respective voltage level among two voltage levels, and
wherein, based on the chip enable information indicating a second operation mode, each nonvolatile memory device of the plurality of nonvolatile memory devices is configured to determine that each chip enable address signal of the chip enable address signals corresponds to a respective level among the at least three voltage levels.

13. The storage device of claim 1, wherein each nonvolatile memory device of the plurality of nonvolatile memory devices is configured to receive chip enable information from the storage controller,
wherein, based on the chip enable information indicating a first operation mode, each nonvolatile memory device of the plurality of nonvolatile memory devices is configured to determine that a corresponding signal among the chip enable signals is activated, and
wherein, based on the chip enable information indicating a second operation mode, each nonvolatile memory device of the plurality of nonvolatile memory devices is configured to determine that each of the chip enable address signals corresponds to any level among the at least three voltage levels.

14. The storage device of claim 1, wherein each nonvolatile memory device of the plurality of nonvolatile memory devices is configured to:
receive a plurality of voltages and chip enable information from the storage controller; and
select the at least three voltage levels among the plurality of voltages based on the chip enable information.

15. An operation method of a storage device that includes a plurality of nonvolatile memory devices and a storage controller, the method comprising:
activating, at the storage controller, a reduced chip enable signal to be transferred to the plurality of nonvolatile memory devices; and
generating, at the storage controller, each chip enable address signal of a plurality of chip enable address signals to be transferred to the plurality of nonvolatile memory devices by using one of at least three voltage levels.

16. The method of claim 15, further comprising:
determining at the plurality of nonvolatile memory devices, in response to the activation of the reduced chip enable signal, that each chip enable address signal of the plurality of chip enable address signals corresponds to a respective level among the at least three voltage levels.

17. The method of claim 16, wherein a first nonvolatile memory device of the plurality of nonvolatile memory devices is activated in response to determining respective levels of the chip enable address signals.

18. The method of claim 15, further comprising:
selecting, at the storage controller, a first operation mode of a plurality of operation modes; and
determining, at the storage controller and the plurality of nonvolatile memory devices, a way to process the reduced chip enable signal and the chip enable address signals, depending on the first operation mode of the plurality of operation modes.

19. The method of claim 15, further comprising:
supplying, at the storage controller, a plurality of voltages to the plurality of nonvolatile memory devices;
transmitting, at the storage controller, chip enable information to the plurality of nonvolatile memory devices; and
in response to receiving the chip enable information, selecting, at the plurality of nonvolatile memory devices, the at least three voltage levels among the plurality of voltages.

20. A memory device comprising:
a memory cell array including a plurality of memory cells;
a row decoder connected to rows of the plurality of memory cells;
a page buffer connected to columns of the plurality of memory cells; and
control logic configured to receive a reduced chip enable signal and a plurality of chip enable address signals from an external device and to determine whether to activate the row decoder and the page buffer based on the chip enable address signals,
wherein the control logic is configured to determine that each of the chip enable address signals corresponds to a respective level among at least three voltage levels, based on activation of the reduced chip enable signal.
